(19) United States
(12) Patent Application Publication
(10) Pub. No.: US 2007/0152218 A1
(43) Pub. Date: Jul. 5, 2007

(54) ACTIVE COMPONENT ARRAY SUBSTRATE

(75) Inventor: Meng-Yi Hung, Taoyuan (TW)

Correspondence Address: J C PATENTS, INC., 4 VENTURE, SUITE 250, IRVINE, CA, 92618, US

(73) Assignee: QUANTA DISPLAY INC., Taoyuan (TW)

(21) Appl. No.: 11/536,408

(22) Filed: Sep. 28, 2006

(30) Foreign Application Priority Data
Dec. 30, 2005 (TW) 94147534

(51) Int. Cl. H01L 29/04

(52) U.S. Cl. 257/59

(57) ABSTRACT

Scan lines and data lines are disposed in a display region of a substrate, and multiple pixel regions are divided thereon. Switch components are disposed in the pixel regions, and each switch component is electrically connected to the scan line and data line. Pixel electrodes are disposed in the pixel regions and each pixel electrode is electrically connected to the switch component. Wires are disposed in a non-display region of the substrate, and at least one portion of each wire includes a first and a second conductor layer, wherein the second conductor layer is disposed on the first conductor layer and parallel-connected to the first conductor layer. The first conductor layer and one of the scan lines, data lines, and the pixel electrodes are in the same layer. The second conductor layer and another one of the scan lines, data lines, and the pixel electrodes are in the same layer.

### CROSS-REFERENCE TO RELATED APPLICATION

This application claims the priority benefit of Taiwan application serial no. 94147534, filed on Dec. 30, 2005. All disclosure of the Taiwan application is incorporated herein by reference.

### BACKGROUND OF THE INVENTION

1. Field of Invention

The present invention relates to a component array substrate, more particularly, to an active component array substrate.

2. Description of Related Art

With the continuously increasing demand for displays, the manufacturers in the field exert their efforts to the development of relative displays. Among all kinds of displays, the cathode ray tube (CRT) has ranked first in the display market due to its excellent display quality and mature technology. However, with the prevalence of the concept of “green” environmental protection, due to the properties of large power consumption and radiation, as well as limited flat space for the product, the CRT may not satisfy the market trend for being light, thin, short, small, chic, and low in power consumption. Therefore, the thin film transistor liquid crystal display (TFT LCD) with the advantages of high resolution, high space utilization efficiency, low power consumption, radiation free, etc., has gradually become the mainstream of the market. However, as the size of current liquid crystal displays has gradually become increasingly large, the length of metal wires within liquid crystal displays is also gradually increased, such that the impedance increase of the metal wires and the signal delay are more and more acute.

FIG. 1 illustrates a top view of a conventional thin film transistor array substrate. Referring to FIG. 1, the conventional thin film transistor array substrate 100 includes a substrate 110, a plurality of scan lines 120, a plurality of data lines 130, a plurality of thin film transistors 140, a plurality of pixel electrodes 150, a plurality of wires 160, and a plurality of pads 170, wherein the substrate 110 is divided into a display region 110a and a non-display region 110b. Moreover, scan lines 120 and data lines 130 are disposed in the display region 110a. The scan lines 120 and the data lines 130 divide the display region 110a into a plurality of the pixel regions 110c. Further, thin film transistors 140 are disposed in pixel regions 110c respectively, wherein these thin film transistors 140 are controlled by these scan lines 120 and data lines 130.

Pixel electrodes 150 are disposed in pixel regions 110c respectively, and each pixel electrode 150 is electrically connected to the corresponding thin film transistor 140. Moreover, pads 170 and wires 160 are disposed in the non-display region 110b, and each wire 160 is respectively connected to the corresponding pad 170 and the scan line 120 or the data line 130. For example, the electronic signals are normally input into pixel electrodes 150 via pads 170, wires 160, data lines 130, and thin film transistors 140 in sequence. However, due to the different length of each wire 160, there is an impedance difference among wires 160. More particularly, the impedance difference between any two wires 160 can be represented as:

$$\vert \frac{L 2}{W 2} - \frac{L 1}{W 2} \vert \times ω1$$

The above ω1 is the surface resistance of wires 160; L is the length of wires 160; and W is the width of wires 160. It can be known from the above equation that when the width W is fixed, the impedance difference is directly proportional to the length difference between any two wires 160. When the impedance difference between any two wires 160 is much bigger, non-uniform displaying is more likely to occur when the liquid crystal display with such a conventional thin film transistor array substrate 100 displays images.

### SUMMARY OF THE INVENTION

In view of the above, an object of the present invention is to provide an active component array substrate for reducing the impedance difference among wires in the non-display region.

Based on the above or other objects, the present invention provides an active component array substrate, which includes a substrate, a plurality of scan lines, a plurality of data lines, a plurality of switch components, a plurality of pixel electrodes, and a plurality of first wires, wherein the substrate includes a display region and a non-display region. The scan lines and data lines are disposed in the display region and the scan lines and the data lines divide the display region into a plurality of the pixel regions. The switch components respectively disposed in pixel regions are electrically connected to the scan lines and data lines. The pixel electrodes are respectively disposed in pixel regions, and each pixel electrode is electrically connected to the corresponding switch component. The first wires are disposed in the non-display region, at least one portion of each of which includes a first conductor layer and a second conductor layer, wherein the first conductor layer is disposed on the substrate, and the second conductor layer is disposed on the first conductor layer and is electrically parallel-connected to the first conductor layer. The first conductor layer and one of the scan lines, the data lines, and the pixel electrodes are in the same layer. The second conductor layer and another one of the scan lines, the data lines, and the pixel electrodes are in the same layer.

According to the embodiments of the present invention, each of the first wires may be respectively connected to one of the scan lines or one of the data lines.

According to the embodiments of the present invention, the active component array substrate further includes a plurality of second wires disposed in the non-display region, and each of the second wires and the scan lines or data lines are in the same layer.

According to the embodiments of the present invention, the length of each first wire is larger than that of each second wire.

According to the embodiments of the present invention, each second wire is connected to one of the scan lines or one of the data lines.

According to the embodiments of the present invention, each first wire further includes a first dielectric layer sandwiched between the first conductor layer and the second conductor layer. The first dielectric layer has a plurality of first contact holes for exposing part of the first conductor layer. The second conductor layer covers the first contact holes, and is electrically parallel-connected to the first conductor layer.

According to the embodiments of the present invention, each first wire further includes a third conductor layer disposed on the second conductor layer. The first conductor layer, the second conductor layer, and the third conductor layer are electrically connected in parallel. The first conductor layer and the scan lines are in the same layer; the second conductor layer and the data lines are in the same layer; and the third conductor layer and the pixel electrodes are in the same layer.

According to the embodiments of the present invention, each first wire further includes a first dielectric layer and a second dielectric layer, wherein the first dielectric layer is disposed between the first conductor layer and the second conductor layer; and the second dielectric layer is disposed between the second conductor layer and the third conductor layer. The second dielectric layer has a plurality of second contact holes for exposing part of the second conductor layer. The third conductor layer covers the second contact holes, and is electrically parallel-connected to the second conductor layer. Moreover, there is a plurality of first contact holes within the first dielectric layer and the second dielectric layer for exposing part of the first conductor layer. The third conductor layer covers the first contact holes, and is electrically parallel-connected to the first conductor layer.

According to the embodiments of the present invention, each first wire further includes a first dielectric layer disposed between the first conductor layer and the second conductor layer. The first dielectric layer has a plurality of first contact holes for exposing part of the first conductor layer. The second conductor layer covers the first contact holes, and is electrically parallel-connected to the first conductor layer.

According to the embodiments of the present invention, each first wire further includes a second dielectric layer disposed between the second conductor layer and the third conductor layer. The second dielectric layer has a plurality of second contact holes for exposing part of the second conductor layer. The third conductor layer covers the second contact holes, and is electrically parallel-connected to the second conductor layer.

According to the embodiments of the present invention, the active component array substrate further includes a plurality of pads disposed in the non-display region. One end of each first wire is connected to one of the pads.

According to the embodiments of the present invention, the switch component can be a thin film transistor.

According to the above, the present invention utilizes multiple parallel-connected conductor layers as part of or all of the wires in the non-display region. Therefore, compared with the conventional technique where the wires all employ a single conductor layer, the present invention is able to reduce the impedance difference between wires, so that non-uniform image displaying is improved.

In order to make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

FIG. 1 illustrates a top view of a conventional thin film transistor array substrate.

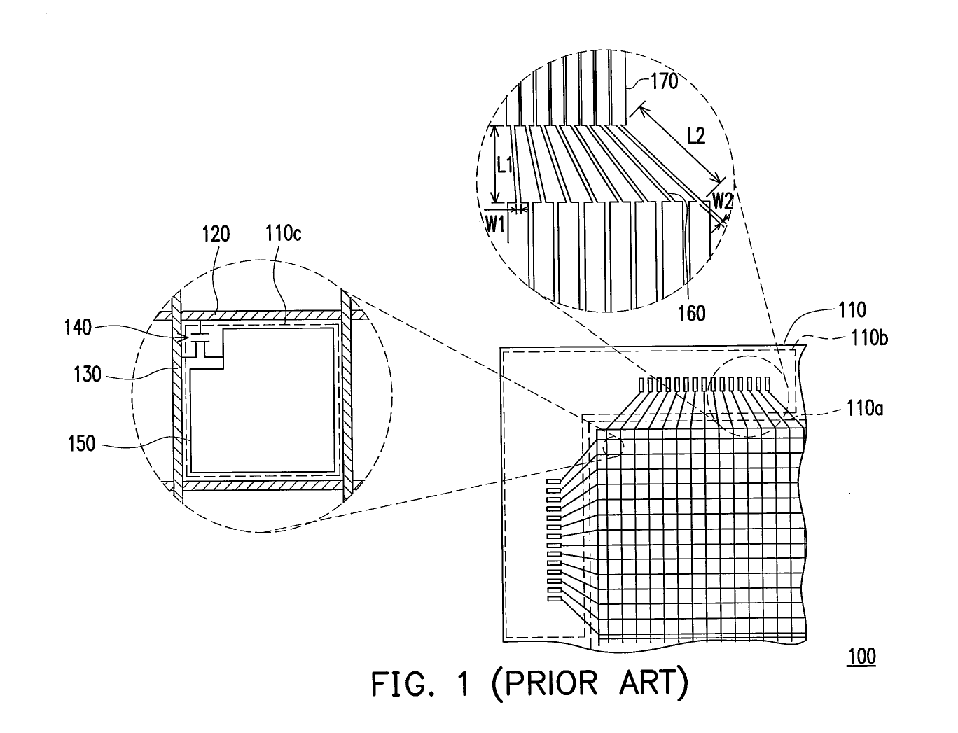

FIG. 2A illustrates a top view of an active component array substrate according to a first preferred embodiment of the present invention.

FIG. 2B illustrates a cross-sectional view along the A-A′ line of FIG. 2A.

FIG. 2C illustrates a cross-sectional view of another first wire according to the first preferred embodiment of the present invention.

FIGS. 3A to 3E illustrate cross-sectional views of the first wire according to a second preferred embodiment of the present invention.

### DESCRIPTION OF EMBODIMENTS

### First Embodiment

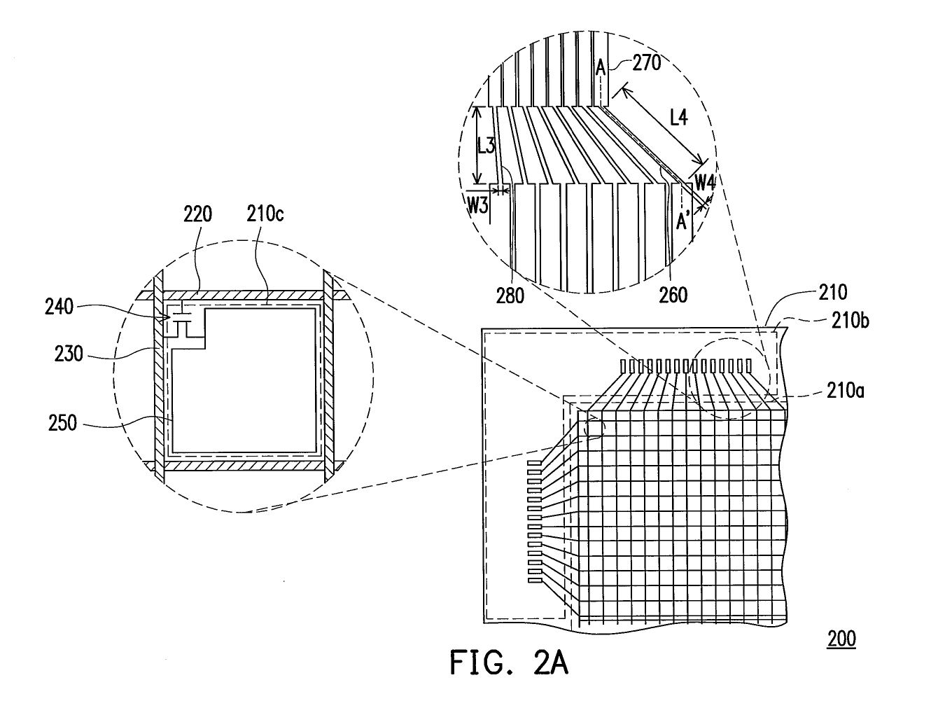

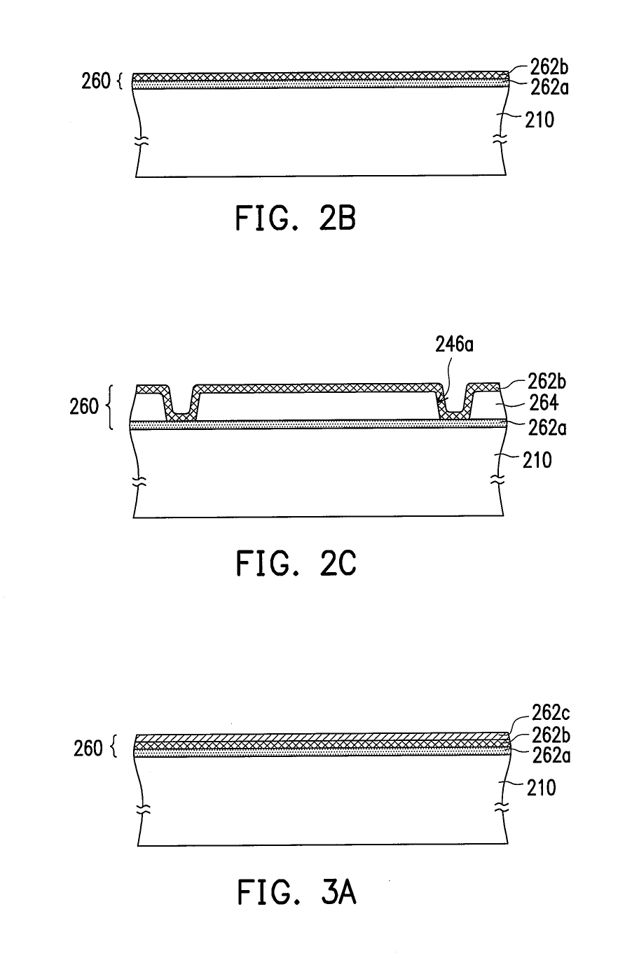

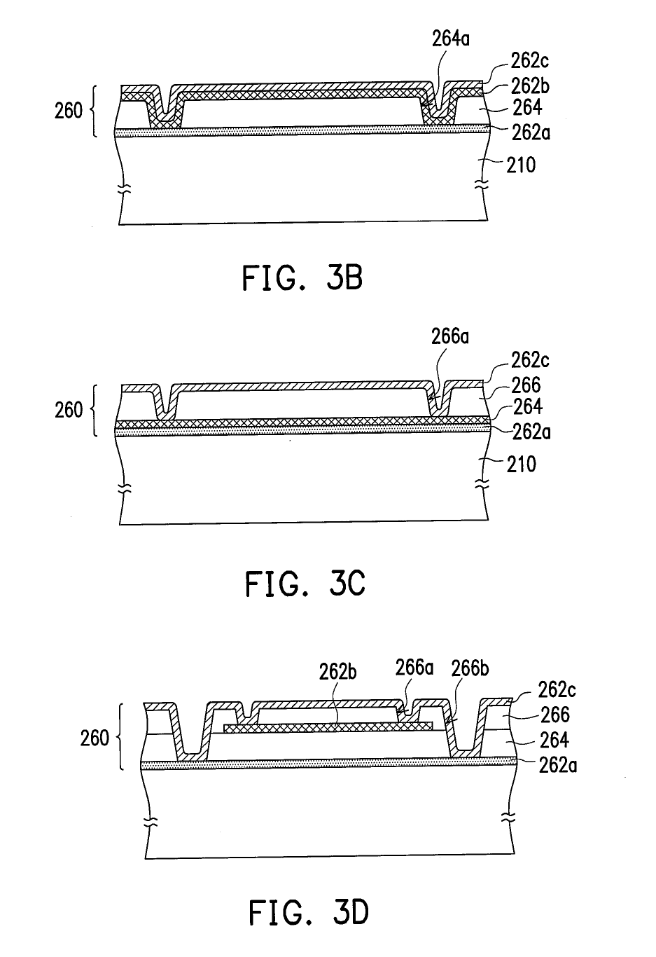

FIG. 2A illustrates a top view of an active component array substrate according to the first preferred embodiment of the present invention, and FIG. 2B illustrates a cross-sectional view along the A-A′ line of FIG. 2A. Referring to FIGS. 2A and 2B, the active component array substrate 200 of this embodiment includes a substrate 210, a plurality of scan lines 220, a plurality of data lines 230, a plurality of switch components 240, a plurality of pixel electrodes 250, a plurality of first wires 260, a plurality of second wires 280, and a plurality of pads 270, wherein the substrate 210 includes a display region 210a and a non-display region 210b. Moreover, the scan lines 220 and data lines 230 are disposed in the display region 210a. The scan lines 220 and the data lines 230 divide the display region 210a into a plurality of the pixel regions 210c. Further, the switch components 240 are respectively disposed in the pixel regions 210c, and are controlled by the scan lines 220 and the data lines 230. In addition, the switch components 240 can be thin film transistors, for example.

The pixel electrodes 250 are respectively disposed in the pixel regions 210c, and the pixel electrodes 250 are electrically connected to the corresponding switch component 240 respectively. In addition, the pads 270, the first wires 260, and the second wires 280 are all disposed in the non-display region 210b, wherein each of the second wires 280 is formed by a single conductor layer. For example, each second wire 280 and the scan lines 220 or data lines 230 are in the same layer. Moreover, the length of each first wire 260 is longer than that of each second wire 280. In this embodiment, each first wire 260 and each second wire 280 may be connected to the pads 270 and the scan lines 220 or data lines 230 respectively. More particularly, at least one portion of each first wire 260 includes a first conductor layer 262a and a second conductor layer 262b, wherein the first conductor layer 262a is disposed on the substrate 210, and the second conductor layer 262b is disposed on the first conductor layer 262a and is electrically parallel-connected to the first conductor layer 262a. For example, electronic signals can be input to the pixel electrodes 250 via the pads 270, the first wires 260, the data lines 230, and the switch components 240 in sequence. Alternatively, the electronic signals also can be input to the pixel electrodes 250 via the pads 270, the second wires 280, the data lines 230, and the switch components 240 in sequence.

In this embodiment, the first conductor layer 262a and the scan lines 220 may be in the same layer, and the second conductor layer 262b and the data lines 230 are in the same layer. Alternatively, the first conductor layer 262a and the scan lines 220 can be in the same layer, and the second conductor layer 262b and the pixel electrodes 250 can be in the same layer. Or, the first conductor layer 262a and the data lines 230 may be in the same layer, and the second conductor layer 262b and the pixel electrodes 250 are in the same layer. It may be known from the above description that the process for forming the first conductor layer 262a and the second conductor layer 262b is compatible with the current process, and no additional processes are required.

According to the above, the second wire 280 is formed by a single conductor layer, and the first wire 260 is formed by multiple conductor layers, thus, the impedance difference between the second wire 280 and the first wire 260 can be represented as:

$$\vert \frac{L 4}{W 4} \times ω 2 - \frac{L 3}{W 3} \times ω1 \vert .$$

The above ω2 is the surface resistance of the parallel-connected first conductor layer 262a and second conductor layer 262b, and ω1 is the surface resistance of the second wire 280 formed by a single conductor layer; L3 is the length of the second wire 280; W3 is the width of the second wire 280; L4 is the length of the first wire 260; W4 is the width of the first wire 260. It should be noted that, in normal conditions, the impedance difference represented by the above equation should be smaller than that derived from the conventional technique. When the impedance difference represented by the above equation is larger than that derived from the conventional technique, the length of multiple layers of conductor wires, the number of stacked conductor layers, or other parameters can be varied by those of ordinary skill in the art to prevent the impedance difference from getting larger.

Since the conventional wire is of a single conductor layer, whereas a part of the wires is varied as multiple parallel-connected conductor layers in the present invention, the first wires 260 of the present invention have lower surface resistance compared with that of the conventional technique. In other words, compared with the conventional technique, the impedance difference between the second wires 280 and the first wires 260 is smaller in the present invention, such that non-uniform image displaying due to the over large impedance difference can be improved. Moreover, the first wires 260 of the present invention are not limited to be connected to the pads 270 and the scan lines 220 or data lines 230. However, the first wires 260 formed by multiple parallel-connected conductor layers also can be used in other circuits disposed in the non-display region 210b to reduce the phenomenon of signal delay or attenuation.

It should be noted that although only the first wires 260 are varied into those with multiple parallel-connected conductor layers in the present invention, the second wires 280 formed by a single conductor layer also can be varied into those with multiple parallel-connected conductor layers. Thus, the impedance difference among wires also can be lowered.

FIG. 2C illustrates a cross-sectional view of another first wire according to the first preferred embodiment of the present invention. Referring to FIG. 2C, the first wire 260 further includes a first dielectric layer 264 disposed between the first conductor layer 262a and the second conductor layer 262b, wherein the first dielectric layer 264 has a plurality of contact holes 264a for exposing part of the first conductor layer 262a. The second conductor layer 262b covers the contact holes 264a, and is electrically parallel-connected to the first conductor layer 262a. In this embodiment, the first dielectric layer 264 can be a gate insulation layer or a passivation layer. When the first dielectric layer 264 is a passivation layer, the contact holes 264a are formed together with the contact holes (not shown) in the switch components 240.

### Second Embodiment

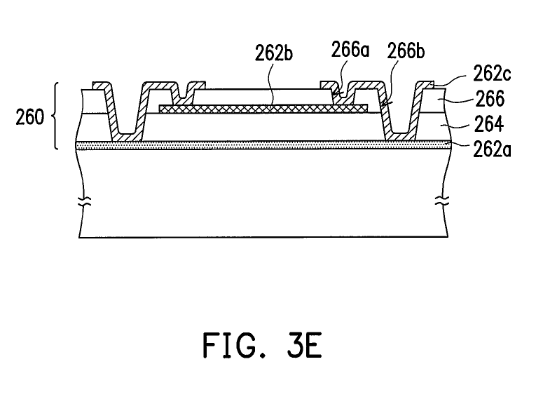

FIGS. 3A to 3E illustrate cross-sectional views of the first wires according to the second preferred embodiment of the present invention. Referring to FIG. 3A first, FIG. 3A is similar to FIG. 2B, with the only difference lying in that: to further reduce the impedance, the first wire 260 further includes a third conductor layer 262c disposed on the second conductor layer 262b. The first conductor layer 262a, the second conductor layer 262b, and the third conductor layer 262c are electrically parallel-connected. In this embodiment, the first conductor layer 262a and the scan lines 220 may be in the same layer; the second conductor layer 262b and the data lines 230 may be in the same layer; and the third conductor layer 262c and the pixel electrodes 250 may be in the same layer.

Referring to FIG. 3B, FIG. 3B is similar to FIG. 2C, with the only difference lying in that: after the second conductor layer 262b is formed, the third conductor layer 262c is formed on the second conductor layer 262b. Since the second conductor layer 262b is electrically parallel-connected to the first conductor layer 262a via the contact holes 264a, and the third conductor layer 262c is disposed on the second conductor layer 262b, the first conductor layer 262a, the second conductor layer 262b, and the third conductor layer 262c are electrically connected in parallel.

Referring to FIG. 3C, FIG. 3C is similar to FIG. 3A, with the only difference lying in that: the first wire 260 further includes a second dielectric layer 266 disposed between the second conductor layer 262b and the third conductor layer 262c. The second dielectric layer 266 has a plurality of contact holes 266a for exposing part of the second conductor layer 262b. Moreover, since the third conductor layer 262c covers the contact holes 266a, the third conductor layer 262c is electrically parallel-connected to the second conductor layer 262b via the contact holes 266a. The second conductor layer 262b is stacked on the first conductor layer 262a, and the third conductor layer 262c is electrically connected to the second conductor layer 262b via the contact holes 266a, such that the first conductor layer 262a, the second conductor layer 262b, and the third conductor layer 262c are electrically connected in parallel. When the second dielectric layer 266 is a passivation layer, the contact holes 266a are formed together with the contact holes (not shown) in the switch components 240.

Referring to FIG. 3D, FIG. 3D is similar to FIG. 3C, with the only difference lying in that: the first dielectric layer 264 is disposed between the first conductor layer 262a and the second conductor layer 262b, and the second dielectric layer 266 is disposed between the second conductor layer 262b and the third conductor layer 262c. Moreover, the second dielectric layer 266 has a plurality of contact holes 266a for exposing part of the second conductor layer 262b. Further, there is a plurality of contact holes 266b within the first dielectric layer 264 and the second dielectric layer 266, which expose part of the first conductor layer 262a; and the third conductor layer 262c covers the contact holes 266a and 266b, such that the first conductor layer 262a, the second conductor layer 262b, and the third conductor layer 262c are electrically connected in parallel. It should be noted that the contact holes 266a and 266b may be formed together with the contact holes (not shown) in the switch components 240, so the present invention is compatible with the current process.

Referring to FIG. 3E, FIG. 3E is similar to FIG. 3D, with the only difference lying in that: the third conductor layer 262c only covers the contact holes 266a and 266b, and the first conductor layer 262a is electrically parallel-connected to the second conductor layer 262b via the third conductor layer 262c. Also, the contact holes 266a and 266b may be formed together with the contact holes (not shown) in the switch components 240, so the present invention is compatible with the current process.

In summary, the active component array substrate of the present invention at least has the following advantages:

1. Compared with the conventional technique that uses a single conductor layer as the wires in the non-display region, part of or all of the wires with the single conductor layer are varied into those with multiple parallel-connected conductor layers in the present invention, and the wires formed by multiple parallel-connected conductor layers of the present invention have a lower impedance value, so as to alleviate the phenomenon of signal delay or attenuation. Moreover, the impedance difference among wires also can be reduced so as to improve the circumstance of non-uniform image displaying.

2. The active component array substrate of the present invention can be compatible with the current process without additional processes.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An active component array substrate, comprising:
a substrate having a display region and a non-display region;
a plurality of scan lines disposed in the display region;
a plurality of data lines disposed in the display region, wherein the scan lines and the data lines divide the display region into a plurality of the pixel regions;
a plurality of switch components respectively disposed in the pixel regions, and electrically connected to the scan lines and the data lines;
a plurality of pixel electrodes respectively disposed in the pixel regions and electrically connected to the corresponding switch components;
a plurality of first wires disposed in the non-display region, wherein at least one portion of each of the first wires includes:
a first conductor layer disposed on the substrate; and
a second conductor layer disposed on the first conductor layer and electrically parallel-connected to the first conductor layer; wherein the first conductor layer and one of the scan lines, the data lines, and the pixel electrodes are in the same layer, and the second conductor layer and another one of the scan lines, the data lines, and the pixel electrodes are in the same layer.

2. The active component array substrate as claimed in claim 1, wherein each of the first wires is connected to one of the scan lines or one of the data lines.

3. The active component array substrate as claimed in claim 1, further comprising a plurality of second wires disposed in the non-display region, wherein each of the second wires and the scan lines or the data lines are in the same layer.

4. The active component array substrate as claimed in claim 3, wherein the length of each first wire is greater than that of each second wire.

5. The active component array substrate as claimed in claim 3, wherein each of the second wires is connected to one of the scan lines or one of the data lines.

6. The active component array substrate as claimed in claim 1, wherein each of the first wires further comprises a first dielectric layer sandwiched between the first conductor layer and the second conductor layer, wherein the first dielectric layer has a plurality of first contact holes for exposing part of the first conductor layer, and the second conductor layer covers the first contact holes and is electrically parallel-connected to the first conductor layer.

7. The active component array substrate as claimed in claim 1, wherein each first wire further comprises a third conductor layer disposed on the second conductor layer; and the first conductor layer, the second conductor layer, and the third conductor layer are electrically connected in parallel, wherein the first conductor layer and the scan lines are in the same layer; the second conductor layer and the data lines are in the same layer; and the third conductor layer and the pixel electrodes are in the same layer.

8. The active component array substrate as claimed in claim 7, wherein each first wire further comprises:
a first dielectric layer disposed between the first conductor layer and the second conductor layer; and
a second dielectric layer disposed between the second conductor layer and the third conductor layer, and provided with a plurality of second contact holes for exposing part of the second conductor layer, wherein the third conductor layer covers the second contact holes and electrically parallel-connected to the second conductor layer, and there are a plurality of first contact holes within the first dielectric layer and the second dielectric layer to expose part of the first conductor layer, and the third conductor layer covers the first contact holes and is electrically parallel-connected to the first conductor layer.

9. The active component array substrate as claimed in claim 7, wherein each first wire further comprises a first dielectric layer disposed between the first conductor layer and the second conductor layer, and the first dielectric layer has a plurality of first contact holes for exposing part of the first conductor layer, and the second conductor layer covers the first contact holes and is electrically parallel-connected to the first conductor layer.

10. The active component array substrate as claimed in claim 7, wherein each first wire further comprises a second dielectric layer disposed between the second conductor layer and the third conductor layer, and the second dielectric layer has a plurality of second contact holes for exposing part of the second conductor layer, and the third conductor layer covers the second contact holes and is electrically parallel-connected to the second conductor layer.

11. The active component array substrate as claimed in claim 1, further comprising a plurality of pads disposed in the non-display region, wherein one end of each of the first wires is connected to one of the pads respectively.

12. The active component array substrate as claimed in claim 1, wherein the switch components are thin film transistors.
